(19) United States
(12) Patent Application Publication
(10) Pub. No.: US 2019/0064218 A1
(43) Pub. Date: Feb. 28, 2019

(54) PROBING DEVICE

(71) Applicant: SUMITOMO ELECTRIC INDUSTRIES, LTD., Osaka (JP)

(72) Inventor: Yukihiro TSUJI, Osaka (JP)

(73) Assignee: SUMITOMO ELECTRIC INDUSTRIES, LTD., Osaka (JP)

(21) Appl. No.: 16/059,682

(22) Filed: Aug. 9, 2018

(30) Foreign Application Priority Data
Aug. 22, 2017 (JP) 2017-159484

(51) Int. Cl. G01R 1/073; H01S 5/00

(52) U.S. Cl. CPC G01R 1/07342; H01S 5/183; H01S 5/0014; G01R 1/07371

(57) ABSTRACT

A probing device includes: a first probing needle including a first portion, a bent portion and a second portion, the first portion having a probing tip, and the bent portion connecting the first portion with the second portion; a second probing needle including a first portion, a bent portion and a second portion, the first portion having a probing tip, and the bent portion connecting the first portion with the second portion; a supporting member including an insulating base having a principal face and a back face, and the first probing needle and the second probing needle being supported by the insulating base on the back face; and a holder holding the first portions of the first and second probing needles, and the holder being apart from the probing tip of the first probing needle and the probing tip of the second probing needle.

### BACKGROUND OF THE INVENTION

### Field of the Invention

The present invention relates to a probing device. This application claims the benefit of priority from Japanese Patent Application No. 2017-159484 filed on Aug. 22, 2017, which is herein incorporated by reference in its entirety.

### Related Background Art

Japanese Unexamined Patent Application Publication No. 2013-135195, referred to as Patent Document 1, discloses a semiconductor device which can reduce the occurrence of failures in measurement of device characteristics using a probing tool.

Japanese Patent Application Laid-Open No. 2010-258052, referred to as Patent Document 2, discloses a method of burning-in a surface emitting semiconductor laser.

### SUMMARY OF THE INVENTION

A probing device according to one aspect of the present invention includes: a first probing needle including a first portion, a bent portion and a second portion, the first portion having a probing tip, and the bent portion connecting the first portion with the second portion; a second probing needle including a first portion, a bent portion and a second portion, the first portion having a probing tip, and the bent portion connecting the first portion with the second portion; a supporting member including an insulating base, the insulating base having a principal face and a back face, the principal face being opposite to the back face, and the first probing needle and the second probing needle being supported by the insulating base on the back face; and a holder holding the first portion of the first probing needle and the first portion of the second probing needle, the holder electrically isolating the first probing needle from the second probing needle, and the holder being apart from the probing tip of the first probing needle and the probing tip of the second probing needle.

### BRIEF DESCRIPTION OF THE DRAWINGS

The above-described objects and the other objects, features, and advantages of the present invention become more apparent from the following detailed description of the preferred embodiments of the present invention proceeding with reference to the attached drawings.

FIG. 1 is a schematic perspective view showing a measuring apparatus according to an embodiment of the present invention.

FIG. 2 is a plan view showing a holder and probing needles held by the holder.

FIG. 3 is a cross-sectional view taken along line III-III shown in FIG. 2.

FIG. 4A is a schematic view showing a major step in a method of making a semiconductor device with the measurement apparatus according to the embodiment.

FIG. 4B is a schematic view showing a major step in the method according to the embodiment.

FIG. 4C is a schematic view showing a major step in the method according to the embodiment.

FIG. 5A is a view showing a method of making a probing device according to the embodiment.

FIG. 5B is a view showing the method according to the embodiment.

FIG. 5C is a view showing the method according to the embodiment.

FIG. 6 is a plan view showing the top side of the probing device according to the embodiment.

FIG. 7 is a cross-sectional view taken along line VII-VII shown in FIG. 6.

FIG. 8 is a plan view showing the top side of a probing device with optical fibers according to another embodiment.

FIG. 9 is a cross-sectional view taken along line IX-IX shown in FIG. 8.

FIG. 10 is a plan view showing a vertical cavity surface emitting device which can be measured with the probing device.

FIG. 11 is a cross-sectional view, taken along line XI-XI shown in FIG. 10, showing a vertical cavity surface emitting device.

FIG. 12 is a schematic view showing a vertical cavity surface emitting device and a probing device making contact therewith to allow the measurement of the operation characteristics with a measuring apparatus.

FIG. 13A is a graph showing current-optical output characteristics, measured with the measuring apparatus, of a vertical cavity surface emitting laser.

FIG. 13B is a graph showing current-voltage characteristics, measured with the measuring apparatus, of the vertical cavity surface emitting laser.

### DESCRIPTION OF THE EMBODIMENTS

Patent Document 1 shows a technique that brings the probing tool into physical contact with an electrode pad of a surface emitting laser to measure oscillation characteristics (for example, threshold current and slope efficiency) of the surface emitting laser, which is lased by applying voltage and current thereto.

Patent Document 2 shows a technique which brings a probing tool into contact with an electrode of a surface emitting semiconductor laser to apply electrical overstress in current, supplied by a power supply for stress, to the surface emitting semiconductor laser via the probing tool.

In order to obtain operating characteristics of an optical semiconductor device, such as a light receiving device and a light emitting device, the semiconductor optical device is brought into contact with a probing tool at an electrode thereof to measure voltage thereof. Obtaining the operation characteristics needs the measurement with extremely high accuracy. The inventor's findings reveal that Kelvin connections enables highly accurate measurement, and uses both two probing needles, which are brought into contact with one electrode in the semiconductor optical device, and another probing needle, which is brought into contact with the same electrode therein. The Kelvin connections can prevent the occurrence of measurement error due to voltage drop caused by resistance on electrical paths between the tips of the probing needles and a measuring instrument, allowing the accurate measurement for the operation characteristics of the semiconductor optical device.

The miniaturization of the semiconductor optical device reduces electrodes in size. The reduced electrodes hinder two probing needles from simultaneously being aligned with a single electrode of the semiconductor optical device to make contact with the single electrode. What is needed is to provide a probing device that can easily bring two probing needles into contact with the electrode thereof.

A description will be given of embodiments.

A probing device according to an embodiment includes: (a) a first probing needle including a first portion, a bent portion and a second portion, the first portion having a probing tip, and the bent portion connecting the first portion with the second portion; (b) a second probing needle including a first portion, a bent portion and a second portion, the first portion having a probing tip, and the bent portion connecting the first portion with the second portion; (c) a supporting member including an insulating base, the insulating base having a principal face and a back face, the principal face being opposite to the back face, and the first probing needle and the second probing needle being supported by the insulating base on the back face; and (d) a holder holding the first portion of the first probing needle and the first portion of the second probing needle, the holder electrically isolating the first probing needle from the second probing needle, and the holder being apart from the probing tip of the first probing needle and the probing tip of the second probing needle.

The probing device arranges the first portions of the first and second probing needles in a direction intersecting the axis along which the first portions extend, and is provided with the holder that aligns the tip portions of the first and second probing needles with each other. The probing device with the holder makes it easy to bring the tip portions of the first and second probing needles into contact with an electrode of a semiconductor optical device, and accordingly enables Kelvin connection. The first probing needle is provided with the second portion that meets the first portion thereof at the bent portion to form an angle less than 180 degrees, and the second probing needle is provided with the second portion that meets the first portion thereof at the bent portion to form an angle less than 180 degrees. The first and second probing needles with the respective bent portions are brought into contact with the single electrode with pressing force. This pressing force elastically deforms the first portions of the first and second probing needles, and keeps the contacts between the electrode and the tips of the first portions

In the probing device according to an embodiment, the holder includes resin or ceramics. The holder made of one of these materials can hold the first portions of the first and second probing needles and electrically isolates the first and second probing needles from each other. The holder of resin can be fabricated by resin-molding with no machining process.

The probing device may further include a ceramic member, and the tips of the first portions are rasped against the ceramic member to remove dirt from the tips. Repeated use of the probing needles contaminates the tip portions thereof with dirt because of repetitive connection between the tip portions and electrodes. The contaminated tip portions may raise the contact resistance between the tip portions and the electrode, leading to measurement errors. Cleaning the tip portions with the ceramic member eliminates contamination of the tip portions to avoid increase in the contact resistance, resulting in reduction of the measurement errors.

The probing device according to an embodiment further includes a third probing needle, a fourth probing needle and another holder that bundles the third and fourth probing needles at the first portions thereof. The probing device, which includes a first pair of the first and second probing needles, held by the holder, and a second pair of the third and fourth probing needles, held by the other holder, can be electrically connected with a voltage meter between the second portion of the first probing needle and the second portion of the third probing needle and an ammeter and a power supply between the second portion of the second probing needle and the second portion of the fourth probing needle. Bundling the first and second probing needles and the third and fourth probing needles with the respective holders makes it easy to bring the two pairs of the probing needles into contact with respective electrodes of a semiconductor optical device. The probing device can measure the voltage between the electrodes with the voltmeter and the current between the electrodes with the ammeter with extremely high accuracy, thereby obtaining the operating characteristics of the semiconductor optical device from the measurement values.

In the probing device according to an embodiment, the holder has a first opening and a second opening, and the first portion of the first probing needle and the first portion of the second probing needle pass through the first opening and the second opening, respectively.

In the probing device according to an embodiment, the holder has a first through-hole and a second through-hole, and the first portion of the first probing needle and the first portion of the second probing needle pass through the first through-hole and the second through-hole, respectively.

In the probing device according to an embodiment, the holder has one end and another end, and the first through-hole and the second through-hole extend from the one end and the other end.

In the probing device according to an embodiment, the holder has a first holding portion that holds the first portion of the first probing needle, and a second holding portion that holds the first portion of the second probing needle.

In the probing device according to an embodiment, the holder has an inner face that defines the first holding portion and the inner face is in contact with the first probing needle.

The probing device according to an embodiment further includes an optical fiber supported by the insulating base, the optical fiber having a tip end.

In the probing device according to an embodiment, the first probing needle and the second probing needle are press-fitted to the holder. Alternatively, in the probing device according to an embodiment, the first portions of the first and second probing needles are fixed to the holder with adhesive.

In the probing device according to an embodiment, the first portion of the first probing needle has a first part with the probing tip, a second part that is held by the holder, and a third part that is connected to the bent portion of the first probing needle outside the holder.

In the probing device according to an embodiment, the holder aligns the probing tip of the first probing needle and the probing tip of the second probing needle with each other.

In the probing device according to an embodiment, a distance between the probing tip of the first probing needle and the probing tip of the second probing needle is not more than 50 micrometers.

In the probing device according to an embodiment, the supporting member has a first conductor and a second conductor, the first conductor and the second conductor are supported by the insulating base, and the first conductor and the second conductor are connected to the second portion of the first probing needle and the second portion of the second probing needle, respectively.

Teachings of the present invention can be readily understood by considering the following detailed description with reference to the accompanying drawings shown as examples. Referring to the accompanying drawings, embodiments of a probing device according to the present invention will be described below. To facilitate understanding, identical reference numerals are used, where possible, to designate identical elements that are common to the figures.

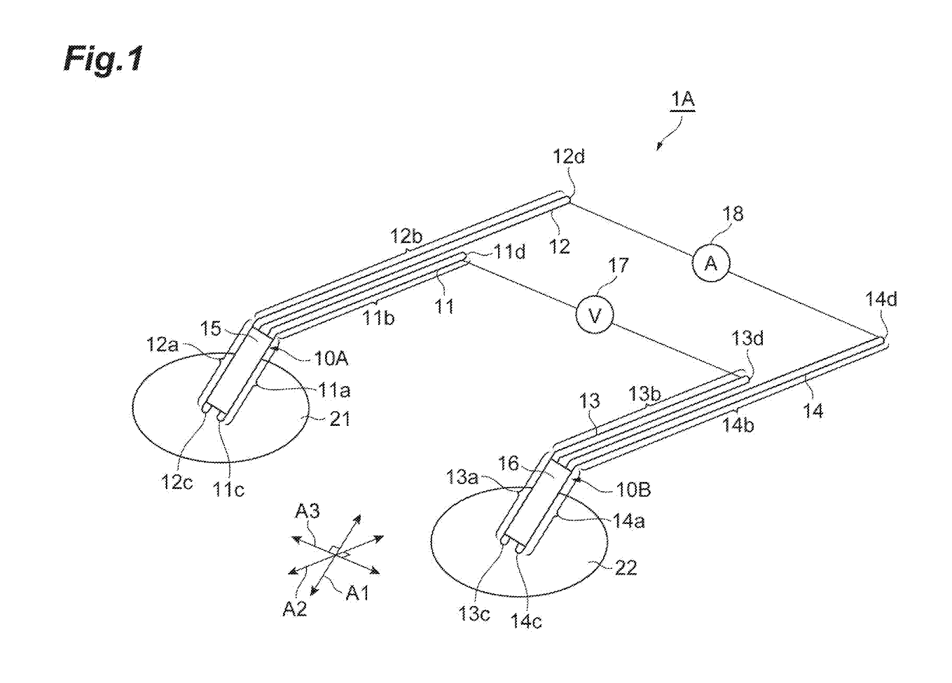

FIG. 1 is a schematic perspective view showing a measuring apparatus according to an embodiment of the present invention. As shown in FIG. 1, the measuring apparatus 1A according to the present embodiment includes a voltmeter 17, an ammeter 18, and a probing device having a first measuring probe 10A and a second measuring probe 10B. This measuring apparatus 1A can be used to determine the operating characteristics of a semiconductor optical device, such as a light receiving device and a light emitting device, specifically a vertical cavity surface emitting laser (abbreviated as VCSEL) with a pair of electrode pads 21 and 22.

The first measuring probe 10A includes a first probing needle 11, a second probing needle 12, and a holder 15. The first probing needle 11 has a rod-like shape (or long, thin piece of metal), and includes a first portion 11a, a second portion 11b and a bent portion, and the first and second portions 11a and 11b are arranged such that the first and second portions 11a and 11b extend straight and that the bent portion connects the first and second portions 11a and 11b with each other. Similarly, the second probing needle 12 has a rod-like shape (or long, thin piece of metal), and includes a first portion 12a, a second portion 12b and a bent portion, and the first and second straight portions 12a and 12b are arranged such that the first and second portions 12a and 12b extend straight and that the bent portion connects the first and second portions 12a and 12b with each other.

The first portions 11a and 12a each extend along the longitudinal direction thereof, for example, the first direction A1, and each have a cross sectional shape of, for example, a circle on a plane the perpendicular to the longitudinal direction. The first and second portions 11a and 12a are arranged along a plane that is defined by the first direction A1 and a direction A3 intersecting (specifically, orthogonal to) the first direction A1, and the direction A3 may intersect the second direction A2 in addition to the first direction A1. The first portions 11a and 12a may be made of metal containing Be and Cu (for example, Be—Cu alloy). The first portions 11a and 12a have respective tip portions 11c and 12c pointing in the first direction A1. The first and second electrical probing needles 11 and 12 are aligned with each other such that the tip portions 11c and 12c are on a plane that is substantially perpendicular to the first direction A1. This alignment allows the tip portions 11c and 12c to make simultaneous contact with a single pad, for example, the electrode pad 21.

The second portions 11b and 12b extend along the longitudinal direction thereof, for example, a second direction A2 which is inclined to the first direction A1, to meet the other ends of the first portions 11a and 12a, respectively. The second portions 11b and 12b each have a cross sectional shape of, for example, a circle on a plane perpendicular to the longitudinal direction thereof. The second portions 11b and 12b are inclined to the first portions 11a and 12a, respectively, to form initial respective inclination angles therebetween, for example 45 degrees, which the probing device out of use has. The probing device in use makes direct contact with the electrode pad 21 of the semiconductor optical device at the tip portions 11c and 12c thereof to elastically deform the first and second portions 11a and 11b (12a and 12b), so that the first portions 11a and 12a thus deformed form respective deformation angles, for example 30 degrees, which is different from the initial angles, with the second portions 11b and 12b. The second portions 11b and 12b may be made of the same metal as that of the first portions 11a and 12a. Alternatively, the second portions 11b and 12b may be made of metal different from that of the first portions 11a and 12a. Further, the second portions 11b and 12b each may have the same cross sectional shape on a plane perpendicular to the longitudinal direction as that of each of the first portions 11a and 12a. The second portions 11b and 12b have rear ends 11d and 12d, respectively, which are opposite to the tips of the first portions 11a and 12a. The second portions 11b and 12b are electrically connected to one terminal of the voltmeter 17 and one terminal of the ammeter 18, for example, at the rear ends 11d and 12d, respectively.

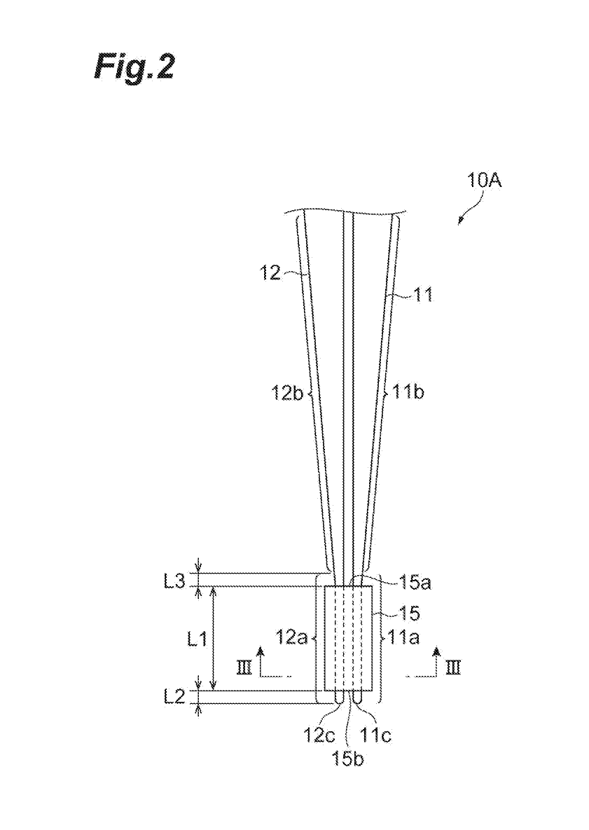

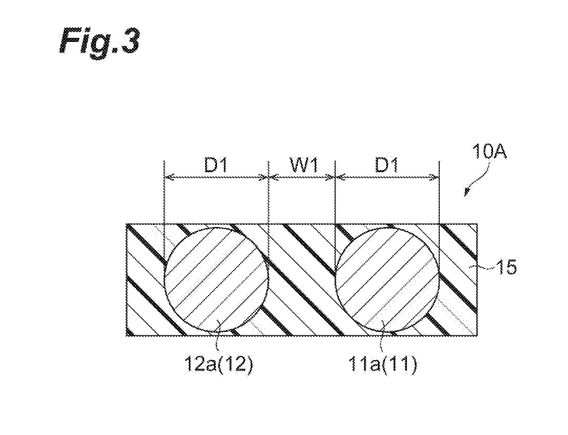

The holder 15 includes an insulating member that bundles the first portion 11a and 12a of the first and second probing needles 11 and 12. FIG. 2 is a plan view showing a holder, and multiple probing needles held by the holder. FIG. 3 is a cross-sectional view taken along line III-III shown in FIG. 2. Referring to FIGS. 2 and 3, the holder 15 binds the first portions 11a and 12a. Specifically, the first and second probing needles 11 and 12 are fixed to the holder 15 in the vicinities of the tip portions 11c and 12c. More specifically the holder 15 annularly covers the parts of the first portions 11a and 12a such that the tip portions 11c and 12c protrude from one end of the holder 15, thereby gripping the first portions 11a and 12a. In an exemplary holder 15, the holder 15 has one end face 15a and another end face 15b, which are arranged in the first direction A1. The first portions 11a and 12a penetrate through the holder 15, which has two holding portions, such as openings, extending from the one end face 15a to the other end face 15b. Specifically, the first portions 11a and 12a enter the holder 15 at the one end face 15a and come out of the holder 15 at the other end face 15b. As shown in FIG. 3, the holder 15 has a rectangular shape in cross section taken along III-III line, which is perpendicular to the first direction A1. In the present embodiment, the holder 15 has a shape, such as rectangular parallelepiped shape. The end faces 15a and 15b are apart from the tip portions 11c and 12c and the respective bent portions between the first portions 11a and 12a and the second portions 11b and 12b, and the tip portions 11c and 12c and the bent portions are not covered with the holder 15.

The holder 15 is made of, for example, ceramic, resin, such as epoxy, and both of them. Alternatively, the holder 15 may be made of another insulating material or a combination of the above materials including resin and ceramic. The holder 15 of resin can be formed by molding, and resin molding can form, for example, the holder 15 of a shape shown in FIGS. 2 and 3. In the present embodiment, the holder 15 has multiple through-holes allowing the first portions 11a and 12a of the probing needles 11 and 12 to be press-fitted or adhere to the holder, so that the first portions 11a and 12a pass through the respective through-holes to be fixed to the holder 15, and in the holder 15, the first portions 11a and 12a are apart from each other and the sides of the holder 15.

Referring to FIG. 1 again, the second measuring probe 10B has a structure that is the same as or similar to that of the first measuring probe 10A. Specifically, the second measuring probe 10B includes a first probing needle 13, a second probing needle 14 and a holder 16. The first probing needle 13 has a rod-like shape (or long, thin piece of metal), and includes a first portion 13a, a second portion 13b and a bent portion, and the first and second portions 13a and 13b are arranged such that the first and second portions 13a and 13b are straight, and the bent portion connects the first and second portions 13a and 13b with each other. The second probing needle 14 also has a rod-like shape (or long, thin piece of metal), and includes a first portion 14a, a second portion 14b and a bent portion, and the first and second straight portions 14a and 14b are arranged such that the first and second portions 14a and 14b extend straight and that the bent portion connects the first and second portions 14a and 14b with each other.

The first portions 13a and 14a each extend along the longitudinal direction thereof, for example the first direction A1, and each have a cross sectional shape of, for example, a circle on a plane perpendicular to the longitudinal direction. The first and second portions 13a and 14a are arranged along a plane that is defined by the first and third directions A1 and A3. The first portions 13a and 14a may be made of metal containing Be and Cu (for example, Be—Cu alloy). The first portions 13a and 14a have respective tip portions 13c and 14c pointing in the first direction A1. The first and second electrical probing needles 13 and 14 are aligned with each other so as to locate the tip portions 13c and 14c on a plane that is substantially perpendicular to the first direction A1. This allows the tip portions 13c and 14c to make simultaneous contact with a single pad, for example, the electrode pad 22.

The second portions 13b and 14b extend along the longitudinal direction thereof, for example, the second direction A2 inclined to the first direction A1, to meet the other ends of the first portions 13a and 14a, respectively. The second portions 13b and 14b each have a cross sectional shape of, for example, a circle on a plane perpendicular to the longitudinal direction. The second portions 13b and 14b are inclined to the first portions 13a and 14a, respectively, to form respective initial inclination angles, for example 45 degrees, which the probing device out of use has. In the probing device in use, the probing device makes direct contact with the electrode pad 22 of the semiconductor optical device at the tip portions 13c and 14c thereof to elastically deform the first and second portions 13a, 13b, 14a, and 14b, so that the first portions 13a and 14a thus deformed form respective deformation angles, for example 30 degrees, which are different from the initial inclination angles, with the second portions 13b and 14b. The second portions 13b and 14b may be made of the same metal as that of the first portions 13a and 14a. Alternatively, the second portions 13b and 14b may be made of metal different from that of the first portions 13a and 14a. Further, the second portions 13b and 14b each may have the same cross sectional shape on a plane perpendicular to the longitudinal direction as that of each of the first portions 13a and 14a. The second portions 13b and 14b have rear ends 13d and 14d, respectively, which are opposite to the tips of the first portions 13a and 14a. The second portions 13b and 14b are electrically connected to one terminal of the voltmeter 17 and one terminal of the ammeter 18, for example, at the rear ends 13d and 14d, respectively.

The holder 16 includes an insulating member that holds the first portion 13a and 14a of the first and second probing needles 13 and 14. The holder 16 has a shape similar to that of the holder 15 as shown in FIGS. 2 and 3. The holder 16 is made of, for example, ceramic, resin, such as epoxy, and both of them. Alternatively, the holder 16 may be made of another insulating material or a combination of the above materials including resin and ceramic. In the present embodiment, the holder 16 has multiple through-holes allowing the first portions 13a and 14a of the probing needles 13 and 14 to be press-fitted or adhere to the holder, so that the first portions 13a and 14a are fixed to the holder 16 to pass through the respective through-holes such that the first portions 13a and 14a are apart from each other and the sides of the holder 16.

The voltmeter 17 is connected between the second portion 11b of the first measuring probe 10A and the second portion 13b of the second measuring probe 10B, allowing the voltmeter 17 to measure the magnitude of voltage between the electrode pad 21, which makes contact with the tip portion 11c of the probing needle 11, and the electrode pad 22, which makes contact with the tip portion 13c of the probing needle 13. The voltmeter 17 may serve as a power supply that apply voltage of a desired magnitude to the semiconductor device through the first and second probing needles 11 and 13.

The ammeter 18 is connected between the second portion 12b of the first measuring probe 10A and the second portion 14b of the second measuring probe 10B, allowing the ammeter 18 to measure the magnitude of current flowing through the semiconductor device having the electrode pad 21 and the electrode pad 22, which makes contact with the tip portions 12c and 14c of the probing needles 12 and 14.

The probing device includes a supporting member 40A or 40B. The supporting member 40A or 40B has an insulating base made of insulating material, such as glass epoxy, and the insulating base has a principal surface and a back surface opposite to the principal surface. The insulating base has a plate-like member. The first and second measuring probes 10A and 10B may be fixed to the insulating base. This fixture can position the tip portions 11c to 14c of the probing needles 11 to 14 in the first direction A1, and can arrange the tip portions 11c to 14c on a straight line extending along the direction A3. The support member, which arranges the second portions 11b to 14b of the probing needles 11 to 14 on the back side of the insulating base, may be attached to an apparatus which includes the voltmeter 17 and the ammeter 18.

A description will be given of exemplary dimensions according to the embodiment below. The electrode pads 21 and 22 can be circular in a planer shape, and the diameter thereof can be, for example, 60 micrometers. The center-to-center dimension of the first and second measuring probes 10A and 10B can be, for example, 100 micrometers. In the semiconductor optical device of a VCSEL, the interval between the center of the light emitting portion (the light emission face) of the VCSEL and the midpoint of the distance between the tips of the first and second measuring probes 10A and 10B is, for example, 100 micrometers. The holders 15 and 16 each have a length L1 of, for example, 10 millimeters in their longitudinal direction, for example, the first direction A1. The probing needles 11 to 14 have respective tip portions coining out of the front end faces of the holders 15 and 16 that hold the first portions of the probing needles 11 to 14, and the protruding tip portions each have a length L2 of, for example, 1 millimeter in their longitudinal direction, for example, the first direction A1. The probing needles 11 to 14 have respective root portions coining out of the back end faces of the holders 15 and 16 in their longitudinal direction thereof, for example the first direction A1 toward the bent portions between the first portions 11a to 14a and the second portions 11b to 14b, and the root portions each have a length L3 of, for example, 1 millimeter in the longitudinal direction. The first portions 11a to 14a of the probing needles 11 to 14 each have a substantially circular cross sectional shape, and has a diameter D1 of, for example, 10 micrometers. The intervals between the first portions 11a and 12a and between the first portions 13a and 14a in the respective holders are, for example, 10 micrometers.

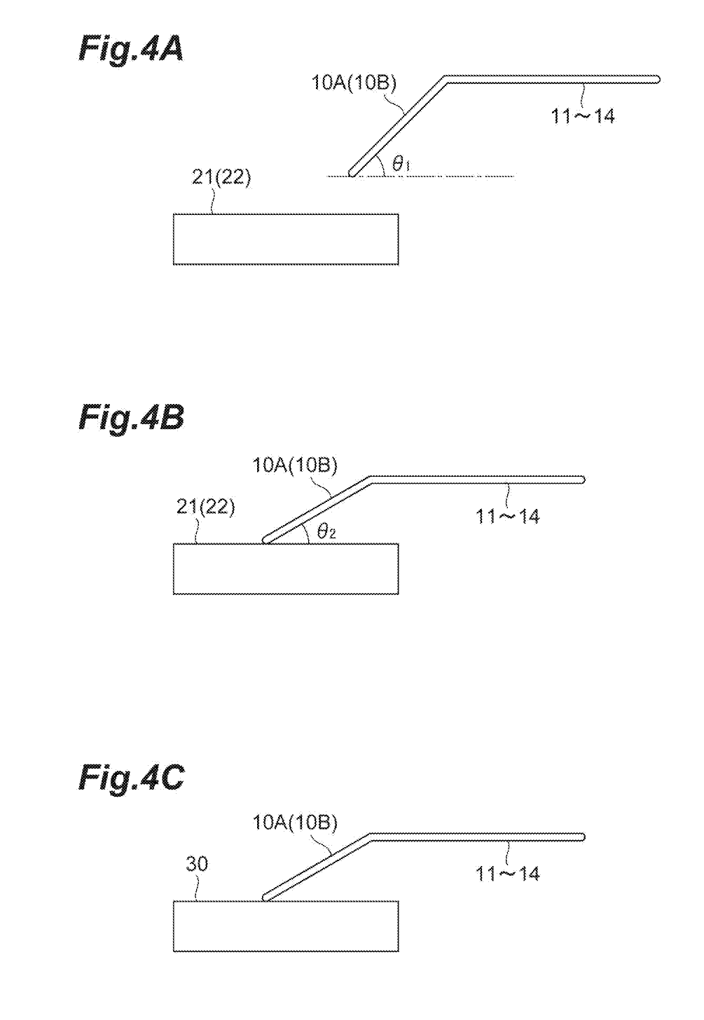

FIGS. 4A to 4C are schematic views each showing a major step of a method for fabricating a semiconductor optical device by use of the measuring apparatus 1A according to the present embodiment. First, as shown in FIG. 4A, a semiconductor optical device is prepared by fabricating the semiconductor optical device having the electrode pads 21 and 22 thereon. The probing needles 11 to 14 are aligned to bring the tip portions 11c to 14c close to the electrode pads 21 and 22 of the semiconductor optical device. In the probing needles 11 to 14 thus aligned, the second portions 11b to 14b of the respective probing needles 11 to 14 are kept parallel to the top faces of the electrode pads 21 and 22. The tip portions 11c to 14c have not yet made contact with the electrode pads 21 and 22, and the first portions 11a to 14a of the probing needles 11 to 14 form respective angles θ1, for example, 45 degrees, with the top faces of the electrode pads 21 and 22.

As shown in FIG. 4B, the probing needles 11 to 12 and 13 to 14 of the probing device are moved toward the electrode pads 21 and 22 to bring the tip portions 11c and 12c and the tip portions 13c and 14c into contact with the electrode pads 21 and 22, respectively. The further moving of the probing device slides the tip portions 11c and 12c and the tip portions 13c to 14c on the top faces of the electrode pads 21 and 22 to elastically deform the probing needles 13 to 14, thereby changing respective angles that the second portions 11b to 14b form with the first portions 11a to 14a. This deformation results in that the angles θ2 between the first portions 11a to 14a of the probing needles 11 to 14 and the top faces of the electrode pads 21 and 22 are, for example, 30 degrees.

The probing needles 11 to 14 thus deformed is used for measurement to allow the tip portions 11c to 14c to make stable contact with the electrode pads 21 and 22. After the measurement, the semiconductor optical device thus measured is marked to indicate the grade thereof, thereby fabricating the semiconductor optical device with excellent device performances. If needed, a ceramic plate 30 is prepared which has a flat surface, as shown in FIG. 4C, and the tip portions 11c to 14c are cleaned with the ceramic plate 30. The tip portions 11c to 14c are rubbed against the surface of the ceramic plate 30 to remove contamination on the tip portions 11c to 14c. The measuring apparatus 1A according to the present embodiment is provided with the ceramic plate 30.

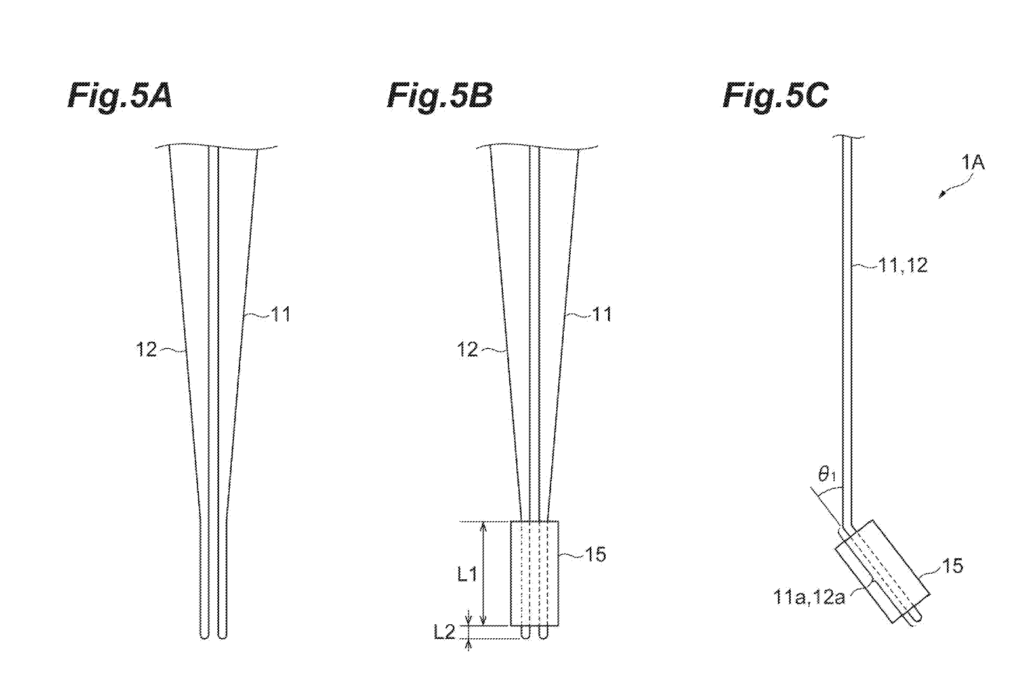

Subsequently, a description will be given of a method of fabricating the first measuring probe 10A according to the present embodiment. FIGS. 5A to 5C are views each showing a major step in a method of fabricating the measuring apparatus 1A. The second measuring probe 10B can be fabricated by the same manner as that of the measuring apparatus 1A. First, as shown in FIG. 5A, straight needles, each of which has a first distal end, a middle portion and a second distal end, are prepared for the first and second probing needles 11 and 12, and these straight needles are arranged in a direction intersecting the longitudinal direction thereof. Referring to FIG. 5B, the straight needles thus arranged are inserted into the holder 15 such that the holder 15 holds the middle portions, each of which has the length L1, of the straight needles and that the first distal ends of the straight needles protrude from the end face of the holder 15 by the length L2, and then are fixed to the holder 15. Referring to FIG. 5C, the straight needles, the middle portions of which are held by the holder 15, are bent by an angle θ1 to form the probing needles 11 and 12. The probing needles 11 and 12 are provided with the first portions 11a and 12a bent with respect to the second portions 11b and 12b, respectively. The above fabricating steps bring the first measuring probe 10A of the present embodiment to completion.

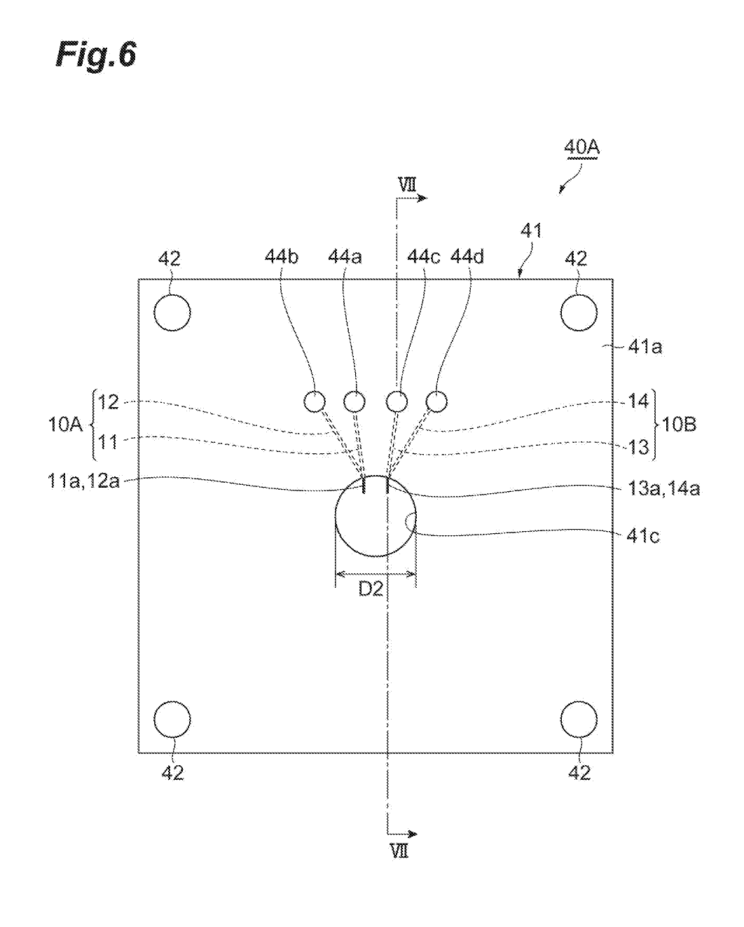

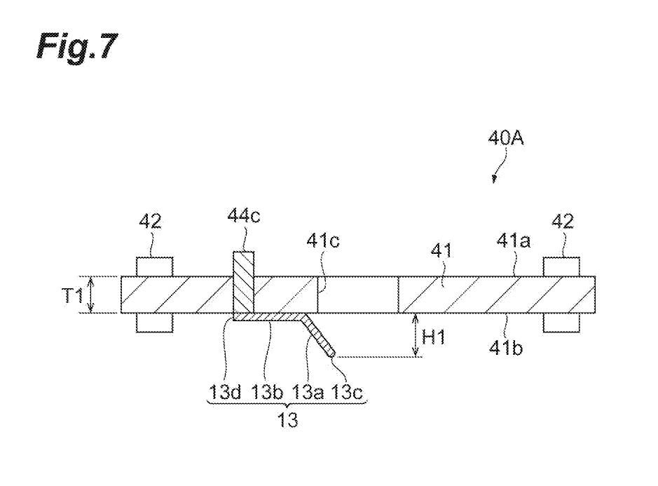

A description will be given of an exemplary supporting member which can support the measuring probes 10A and 10B. FIG. 6 is a plan view showing the supporting member 40A. FIG. 7 is a cross-sectional view taken along line VII-VII shown in FIG. 6. The support member 40A includes a plate-like member 41 which has top and back faces, such as a substantial rectangle or square shape and is made of insulating material. Specifically, the plate-like member 41 has a flat principal surface 41a and a flat back surface 41b opposite to the principal surface 41a. The member 41 has fastenings, such as fixing screws 42, at the four corners thereof. The fixing screws 42 allow the fixture of the probing device to another device. The fixing screws 42 install the member 41 of the probing device on the other device.

Specifically, the member 41 has an opening 41c in the middle thereof. The opening 41c passes through the member 41 from the principal surface 41a to the back surface 41b. The opening 41c has a shape of, for example, a circle at the surfaces 41a and 41b. As shown in FIG. 6, the member 41 supports the second portions 11b to 14b of the probing needles 11 to 14 on the back surface 41b thereof such that the second portions 11b to 14b are directed towards the opening 41c. This supporting results in that the first portions 11a to 14a, which extend across the edge portion of the opening 41c as shown in FIG. 6, each are provided with a part or the whole of the first portion in the opening 41c. As shown in FIG. 7, the second portions 11b to 14b of the probing needles 11 to 14 are arranged on the back surface 41b of the member 41 and fixed to the back surface 41b. Then, the first portions 11a to 14a of the probing needles 11 to 14 are inclined to the back surface 41b (extend obliquely in a direction away from the back surface 41b, for example, the first direction A1). For example, the first direction A1 is inclined with respect to the back surface 41b.

As shown in FIG. 6, the probing needles 11 to 14 have rear ends 11d to 14d, which are connected to terminals 44a to 44d of the supporting member 40A, respectively. The terminals 44a to 44d penetrate the plate-like member 41 in a direction from the back surface to the principal surface. The terminals 44a to 44d provide the probing device with electrical paths from the principal surface 41a of the member 41 to the probing needles 11 to 14. The second portions 11b and 12b extend in respective directions from the bent portions to the rear ends 11d and 12d of the probing needles 11 and 12 while increasing the interval therebetween, and the second portions 13b and 14b extend in respective directions from the bent portions to the rear ends 13d and 14d of the probing needles 13 and 14 while increasing the interval therebetween.

Exemplary dimensions of the support member 40A are shown below. The member 41 can be provided with the principal and back surface each having a shape of, for example, a square with a side of 300 mm. The opening 41c has a diameter D2 of, for example, 50 mm. The member 41 has a thickness Ti (the distance from the principal surface 41a to the back surface 41b) of, for example, 2 mm. The tip portions 11c to 14c of the respective probing needles 11 to 14 are away from the back surface 41b by a height H1 of, for example, 7 mm.

The measuring device 1A according to the present embodiment may be provided with the support member 40A. Specifically, the support member 40A is aligned with a wafer such that the top surface of the wafer is opposed to the back surface 41b of the member 41. The wafer has, for example, device sections, each of which is prepared for the optical semiconductor device, arrayed on the top surface thereof. One of the wafer and the support member 40A is moved relative to the other in the direction that is parallel to the principal surface 41a and the back surface 41b, thereby obtaining the alignment of the wafer and the support member 40A with each other, and specifically, the probing needles 11 to 14 are aligned with one of the device sections of the wafer. Then, one of the wafer and the support member 40A is moved relative to the other in the direction normal to the top surface of the wafer to bring the tip end portions 11c to 14c of the respective probing needles 11 to 14 into contact with the electrode pads of a semiconductor optical device on the device section, allowing the measurement of the operating characteristics of the semiconductor optical device. Using the probing device enables Kelvin connection, which allows the accurate measurement of the operating characteristics of the semiconductor optical device. The repetition of making contact and measurement and the marking can obtain the operating characteristics all over the device sections. The support member 40A can protect the fine first portions 11a to 14a. The probing device allows the optical measurement of a semiconductor device, such as a VCSEL, lasing light of which passes through the opening 41c.

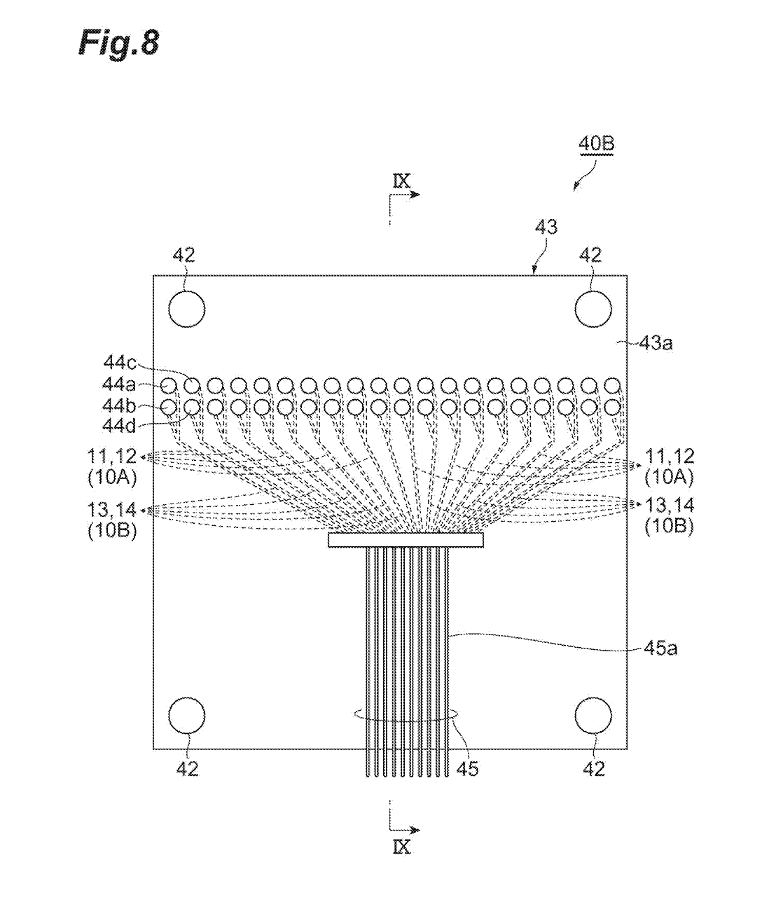

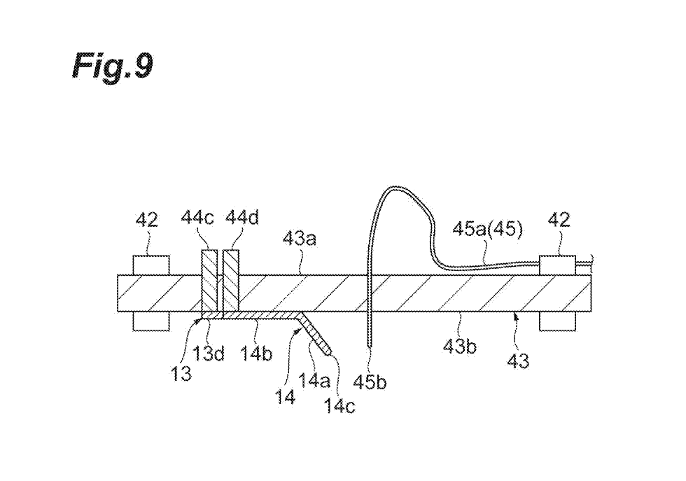

FIG. 8 is a plan view showing a supporting member 40B according to another embodiment. FIG. 9 is a cross-sectional view taken along line IX-IX shown in FIG. 8. The support member 40B is different from the support member 40A in the number of measuring probes and the presence of optical fibers.

Specifically, the support member 40B includes a plate-like member 43 having top and back faces, such as a substantial rectangle or square shape. The plate-like member 43 has a flat principal surface 43a and a flat back surface 43b opposite to the principal surface 43a, and made of insulating material, such as glass epoxy. The member 43 has fastenings, such as fixing screws 42, at the four corners thereof. The fixing screws 42 allow the probing device to be fixed to another device. The fixing screws 42 install the member 43 of the probing device on the other device.

As shown in FIG. 9, multiple pairs of measuring probes (for example, 10 pairs of measuring probes in the drawing), each of which has a pair of measuring probes 10A and 10B, are arranged on the back surface 43b of the member 43. Each measuring-probe pair is provided with the second portions 11b to 14b of the probing needles 11 to 14, which are arranged on the back surface 43b of the member 43 and fixed to the back surface 43b in the middles of the 43. The first portions 11a to 14a of the probing needles 11 to 14 are inclined to the back surface 43b (obliquely away from the back surface 43b). Referring to the illustrative drawing, the first direction A1 is inclined with respect to the back surface 43b. The tip portions 11c to 14c of the multiple pairs of measuring probes are aligned in a line.

As shown in FIG. 8, the second portions 11b and 12b of the probing needles 11 and 12 for the measuring probes 10A and the second portions 13b and 14b of the probing needles 13 and 14 for the measuring probes 10B extend in the direction from the respective bent portion toward the rear ends 11d to 14d thereof while increasing the interval between the adjacent measuring probes 10A and 10B. The rear ends 11d to 14d of the probing needles 11 to 14 are connected to terminals 44a to 44d, respectively, which penetrate the member 43 from the principal surface to the back surface. The terminals 44a to 44d provide the probing needles 11 to 14 with electrical paths from the principal surface 43a of the member 43. The probing device in FIG. 8, which is illustrative, is provided with the terminals 44a to 44d arranged, for example, in two lines, and if needed, the terminals 44a to 44d may be arranged in another manner.

If needed, the probing device further includes an optical fiber bundle 45. The member 43 mounts the optical fiber bundle 45 on the principal surface 43a, and the optical fiber bundle 45 includes multiple optical fibers 45a. The member 43 has one side portion, a middle portion, and another side portion arranged in a line, and the terminals 44a to 44d are arranged along the one side portion. The optical fiber bundle 45 is fixed to the member 43 on the principal surface 43a thereof. The optical fibers 45a extend in a direction from the outer portion of the member 43 toward the inner portion thereof, and pass through holes of the member 43, which are near the center of the member 43, to come out from the holes, so that the tip ends 45b of the optical fibers 45a protrude from the back surface 43b of the member 43. The tip end portions 45b of the fibers extend straight so as to be directed in the same direction, and are arranged along the same direction as that of the direction along which the tip end portions 11c to 14c of the multiple measuring probes are arranged. In addition, the tip end portions 45b are positioned to the arrangement of the tip end portions 11c to 14c of the measuring probes associated therewith. The tip portions 45b each have a lensed end, for example, spherical shaped end, and the lensed end can receive light emitted from a semiconductor optical device, such as VCSEL.

In the present embodiment, the first portions 11a to 14a of the probing needles 11 to 14 may include beryllium (Be) and copper (Cu). Metal allay containing beryllium (Be) and copper (Cu) is softer than that of other measuring probes, such as tungsten, and is less likely to scratch the electrode pads 21 and 22 made of soft metal, such as gold (Au).

In the embodiment, the holders 15 and 16 may be made of resin. Alternatively, the holders 15 and 16 may be made of ceramic. For example, the holder 15 made of one of these materials can grip the first portions 11a and 12a of the probing needles 11 and 12 while maintaining electrical insulation between the probing needles 11 and 12, and the holder 16 made of one of the above materials can grip the first portions 13a and 14a of the probing needles 13 and 14 while maintaining insulation between the probing needles 13 and 14. Particularly, the holders 15 and 16 made of resin can be easily fabricated by resin molding without machining processes.

In the present embodiment, the measuring apparatus 30 may be provided with a ceramic plate, which is used to hone the tip portions 11c to 14c of the first portions 11a to 14a, thereby cleaning the tip portions 11c to 14c. Repeated use of the measuring probes 10A and 10B contaminates the tip end portions 11c to 14c with dirt adhering thereto, and wears out the tip end portions 11c to 14c because of repeated contacts between the tip end portions 11c to 14c and electrode pads. The dirt adhering to the tip portions 11c to 14c may raise contact resistance between the tip portions 11c to 14c and the electrode pads 21 and 22 to increase the measurement errors. Cleaning the tip portions 11c to 14c with the ceramic plate 30 can remove the dirt from the tip portions 11c to 14c to prevent the dirt on the tip portions 11c to 14c from increasing the contact resistance between the tip portions 11c to 14c and the electrode pads 21 and 22.

As seen from the above description, the measuring probes 10A and 10B in the measuring apparatus 1A according to the present embodiment allows the electrode pads 21 and 22 of the semiconductor optical device to make contact with the respective probes. This connection with the measuring apparatus 1A can measure voltage between the electrode pads 21 and 22 using the voltmeter 17 and the current between the electrode pads 21 and 22 using the ammeter 18 to provide the operating characteristics of the semiconductor optical device with extremely high accuracy.

The measuring apparatus according to the present embodiment is used to measure VCSELs. The VCSELs can lase at a current of several mA, resulting in that flowing this amount of current through probes and interconnects in the measuring apparatus may cause an unacceptable voltage drop. The electrode pads 21 and 22 in the VCSEL each have a dimension of, for example, 60 micrometers in diameter, which is very small. The VCSEL arranges not only the electrode pads 21 and 22 but also an emitting face for emitting laser light L on the same side of the VCSEL, and this arrangement on the same face requires the probing needles to extend obliquely to the electrode pads 21 and 22 so as not to intercept the emission of the laser light L. The measuring apparatus 1A with the measuring probes 10A and 10B according to the present embodiment enable Kelvin connection on the electrode pads 21 and 22 of the VCSEL. The probing needles 11 and 12 are held by the holder 15 at the first portions 11a and 12a, which make contact with the top face of the electrode pad 21 at an angle inclined to the top face of the electrode pad 21, whereas the probing needles 13 and 14 are held by the holder 16 at the first portions 13a and 14a, which make contact with the top face of the electrode pad 22 at an angle inclined to the top face of the electrode pad 22. The holding with the holders 15 and 16 at the first portions 11a to 14a, which are close to the respective tip portions, allows the alignment of the tip ends, thereby avoiding the misalignment of the probing needles 11 and 12 and the probing needles 13 and 14 with the electrode pads 21 and 22, respectively, and further reduce the flexure of the first portions 11a to 14a, resulting in that the portions 11c to 14c can be brought into excellent contact with the electrode pads 21 and 22, respectively. Particularly, the flexure of the probing needles 11 to 14 in use may deteriorate the probing needles 11 to 14 made of soft material, such as Be—Cu alloy. The measuring apparatus 1A and the measuring probes 10A and 10B according to the present embodiment are particularly effective in measuring the semiconductor optical device.

### Example

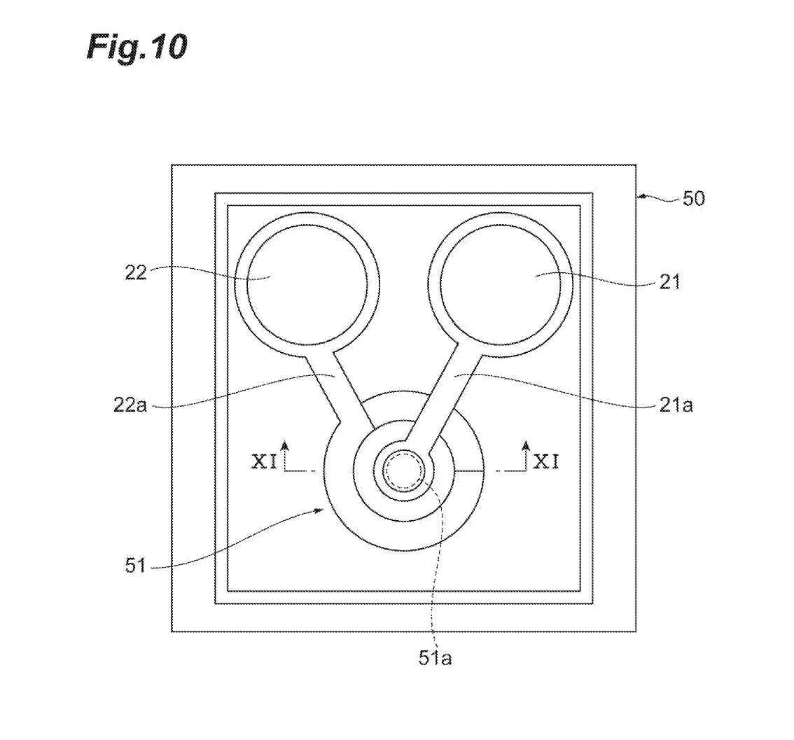

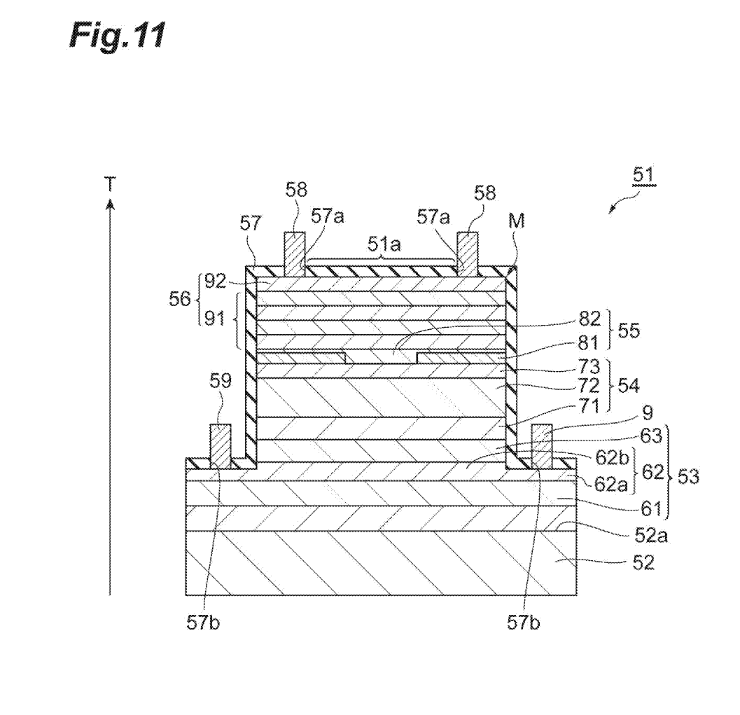

A description will be given of measuring the operation characteristic of the VCSEL. FIG. 10 is a plan view showing a VCSEL 50 prepared for measurement in this example. FIG. 11 is a cross-sectional view, taken along line XI-XI shown in FIG. 10, showing the VCSEL 50. As shown in FIG. 10, the VCSEL 50 is provided with the electrode pads 21 and 22 and a light emitting portion 51. The electrode pads 21 and 22 have respective top faces, each of which has, for example, a circular shape, and are arranged along a side of a substantially square semiconductor support 52 (as shown in FIG. 11) of the VCSEL 50. The semiconductor support 52 has four sides, each of which has a length of, for example, 250 micrometers, and the electrode pads 21 and 22 each have a diameter of, for example, 60 micrometers.

Referring to FIG. 11, the light emitting portion 51 includes a semiconductor substrate 52, a first stack 53, an active layer 54, a current constricting structure 55, a second stack 56, an insulating film 57, an electrodes 58 and 59. The first stack 53, the active layer 54, the current constricting structure 55, and the second stack 56 are sequentially arranged on the semiconductor substrate 52. The light emitting portion 51 is provided with a semiconductor mesa M, which includes a part of the first stack 53, the active layer 54, the current constricting structure 55, and the second stack 56. The direction T is referred to as the direction along which layers (for example, the active layer 54) for the light emitting portion 51 are stacked.

The semiconductor support 52 is made of group III-V semiconductor, for example, an i- or n-type GaAs. The semiconductor support 52 of n-type is doped with an n-type dopant, such as Te (tellurium) or Si (silicon). The group III-V semiconductor may have one or more group III elements including Al (aluminum), Ga (gallium), and In (indium), and one or more group V elements including As (arsenic), and Sb (antimony). The semiconductor optical device is mounted on a circuit board, and the semiconductor support 52 thereof may be processed during the fabrication thereof, for example, by polishing to a thickness ranging from, for example, 100 to 200 micrometers.

The first stack 53 serves as a lower distributed Bragg reflector (abbreviated as a lower DBR), which mounts the active layer 54, and includes multiple semiconductor layers. Specifically, the first stack 53 is disposed on the principal surface 52a of the semiconductor support 52 and includes, for example, a first superlattice 61, a contact layer 62, and a second superlattice 63, which are sequentially stacked in the direction T on the principal surface 52a of the semiconductor support 52, so that the contact layer 62 is located between the first and second superlattice structures 61 and 63.

The first superlattice 61 includes i-type semiconductor layers. The first superlattice 61 has the arrangement of unit structures in each of which has different semiconductor layers alternately stacked. An exemplary unit structure includes an AlGaAs layer (with an Al composition of 0.12) and an AlGaAs layer (with an Al composition of 0.90). The first superlattice 61 has a stacking number of the unit structures of, for example, 50 to 100. The first superlattice 61 has a thickness of, for example, 4000 to 6000 nm.

The contact layer 62 is made of a single film of n-type semiconductor, which is in contact with the electrode 59 in the light emitting portion 51. The contact layer 62 includes, for example, a

GaAs layer doped with Si. The contact layer 62 has a first portion 62a and a second portion 62b which have different thicknesses. The first portion 62a is in contact with the electrode 59 and is outside the semiconductor mesa M. The first portion 62a has a thickness equal to or less than that of the second portion 62b. In view of an excellent contact resistance, the first portion 62a may be provided with a thickness of, for example, 250 to 500 nm. The second portion 62b provides the semiconductor mesa M with an upper part thereof. The thickness of the second portion 62b is, for example, not less than that of the first portion 62a and not more than 500 nm.

The second superlattice 63 is made of n-type semiconductor and is disposed on the second portion 62b of the contact layer 62. The second superlattice layer 63 includes multiple unit structures, each of which has different semiconductor layers alternately stacked which are similar to the first superlattice 61. An exemplary unit structure includes an AlGaAs layer (with an Al composition of 0.12) and an AlGaAs layer (with an Al composition of 0.90). The second superlattice 63 has a stacking number of the unit structures of, for example, 10 to 30. The second superlattice 63 is doped with, for example, Si. The second superlattice 63 has a thickness of, for example, 1000 to 2000 nm.

The active layer 54 generates light through recombination of electrons and holes and is disposed on the second superlattice 63 of the first stack 53. The active layer 54 has a lower spacer layer 71, a multiple quantum well structure 72, and an upper spacer layer 73, which are arranged in order on the first laminate 53 along the direction T. The multiple quantum well structure 72 is disposed between the lower and upper spacer layers 71 and 73. The active layer 54 has a thickness of, for example, 50 to 300 nm.

The lower spacer layer 71 is disposed between the second superlattice 63 and the multiple quantum well structure 72, and includes semiconductor doped with an n-type dopant. An exemplary lower spacer layer 71 is made of, for example, AlGaAs layer doped with Si (with an Al composition of 0.30). The multiple quantum well structure 72 includes, for example, GaAs layers each serving as a well layer and AlGaAs layers each serving as a barrier layer, and the GaAs layers and the AlGaAs layers are alternately arranged. The upper spacer layer 73 includes an undoped semiconductor layer and a semiconductor layer including a p-type dopant. An exemplary undoped semiconductor layer includes an AlGaAs layer (with an Al composition of 0.30). An exemplary p-doped semiconductor layer includes, an AlGaAs layer (with an Al composition of 0.90) containing Zn (zinc dopant). The p-type dopant encompasses Be (beryllium), Mg (magnesium), C (carbon), and Zn.

The current constricting structure 55 constricts current (carriers), which is injected into the active layer 54, in the semiconductor mesa M. The current constricting structure 55 has a high resistance portion 81 and a low resistance portion 82. The low resistance portion 82 is formed of, for example, an AlGaAs layer (with an Al composition of 0.98), and the high resistance portion 81 encircles the low resistance portion 82, and is formed of oxide containing aluminum oxide. The low resistance portion 82 has a lower specific resistance than that the high resistance portion 81, which contains aluminum oxide. The current constricting structure 55 has a thickness of, for example, 10 to 50 nm. The current constricting structure 55 guides current to the low resistance portion 82, which defines an aperture size.

The second stack 56 serves as an upper distributed Bragg reflector (abbreviated as an upper DBR) located on the active layer 54, and includes multiple semiconductor layers. The second stack 56 is disposed on the current constricting structure 55, and has, for example, a superlattice 91 and a contact layer 92. If needed, the current constricting structure 55 may be in the second stack 56, and the superlattice 91 and the contact layer 92 are arranged in order on above the current constricting structure 55 along the direction T.

The superlattice 91 has a p-type conductivity. The superlattice layer 91 includes multiple unit structures alternately stacked, which are similar to the first superlattice 61. An exemplary unit structure includes an AlGaAs layer (with an Al composition of 0.12) and an AlGaAs layer (with an Al composition of 0.90). The superlattice 91 has a stacking number of the unit structures of, for example, 50 to 100. The superlattice has a thickness of, for example, 3000 to 5000 nm. The superlattice 91 is doped with, for example, Zn. The contact layer 92 is formed of a single film of p-type semiconductor in contact with the electrode 58 of the light emitting portion 51. The contact layer 92 is made of, for example, a GaAs doped with Zn. The contact layer 92 has a thickness of, for example, 100 to 300 nm.

The insulating film 57 serves as a protective film for the semiconductor layers in the light emitting portion 51, and is made of, for example, an inorganic insulating film. The inorganic insulating film may include silicon-based material, such as a silicon oxide film, a silicon nitride film, or a silicon oxynitride film. The insulating film 57 has an opening 57a on the semiconductor mesa M and if needed, is provided with an opening 57b outside the semiconductor mesa M. The openings 57a and 57b penetrate through the insulating film 57 in the direction T, so that the opening 57a reaches the contact layer 92, and the opening 57b reaches the first portion 62a of the contact layer 62. The insulating film 57 may have a thickness of 200 to 500 nm in view of a high reflectance to light emitted from the light emitting portion 51

The VCSEL includes an electrode 58, which is disposed on the semiconductor mesa M in the opening 57a. The electrode 58 is in contact with the contact layer 92 via the opening 57a. The electrode 58 has a laminate structure including, for example, a titanium layer, a platinum layer, and a gold layer. The electrode 58 has a looped shape on the top of the semiconductor mesa M, and has an aperture 51a defined by the looped shape of the electrode 58. The VCSEL emits light through the aperture 51a.

The VCSEL includes an electrode 59, which is disposed outside the semiconductor mesa M in the opening 57b. The electrode 59 is in contact with the first portion 62a of the contact layer 62 via the opening 57b. The electrode 59 has a laminate structure including, for example, a gold-germanium-nickel alloy layer. The electrode 59 has a shape of, for example, an arcuate shape, which has a shape defined by omitting a part of a ring.

Referring again to FIG. 10, the electrode pad 21 is electrically connected to the electrode 58 via a wiring conductor 21a which extends on the insulating film 57. The electrode pad 22 is electrically connected to the electrode 59 via a wiring conductor 22a which extends on the insulating film 57. Current is supplied to the VCSEL through the electrode pads 21 and 22, and the active layer 54 generates light in the light emitting portion 51 to emit laser light from the light emitting region 51a.

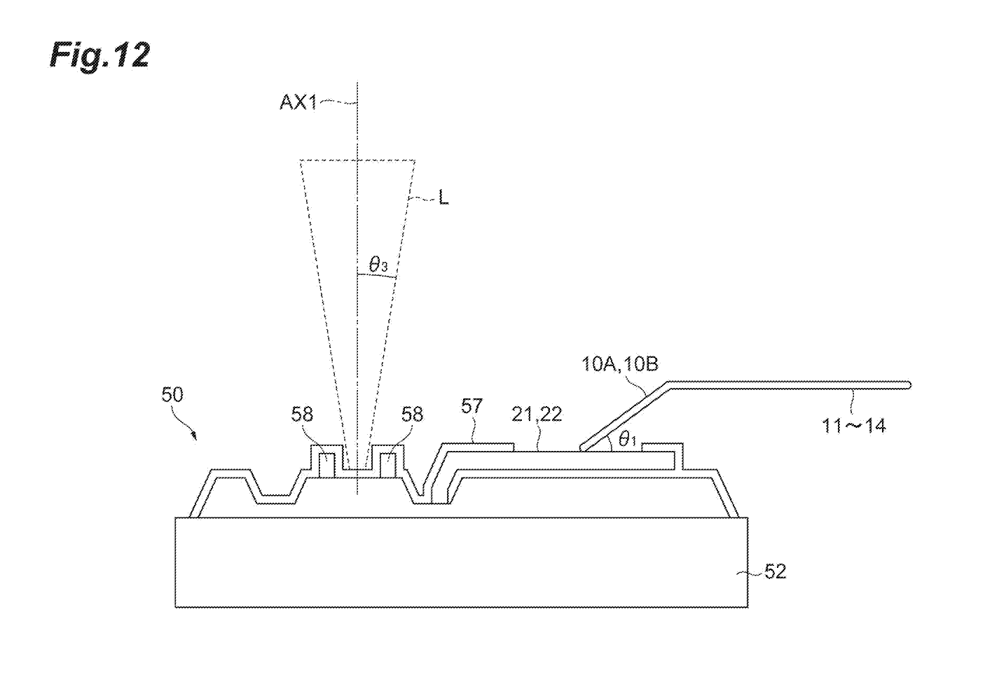

FIG. 12 is a schematic view showing the connection of the VCSEL 50 with the probe device for measuring the device characteristics of the VCSEL 50. In this connection, the tip portions 11c and 12c of the measuring probe 10A are brought into contact with the electrode pad 21, and the tip portions 13c and 14c of the measuring probe 10B is brought into contact with the electrode pad 22. As shown in the figure, the first portions 11a to 14a of the probing needles 11 to 14, which are in contact with the respective top faces of the electrode pads, extend obliquely away from the semiconductor mesa, thereby allowing the laser light L to propagate upward. The measuring probes 10A and 10B, which are arranged to position the rear ends 11d to 14d away from semiconductor mesa with respect to the electrode pads that are in contact with the tip portions 11c to 14c, can avoid the light propagating path normal to the top of the semiconductor mesa. The VCSEL emits a laser beam L in a divergence angle θ3 of, for example, 30 degrees with respect to the optical axis Ax1. The first portions 11a to 14a may form an inclination angle θ1, which is associated with the spread angle θ3, with respect to the top faces of the electrode pads,

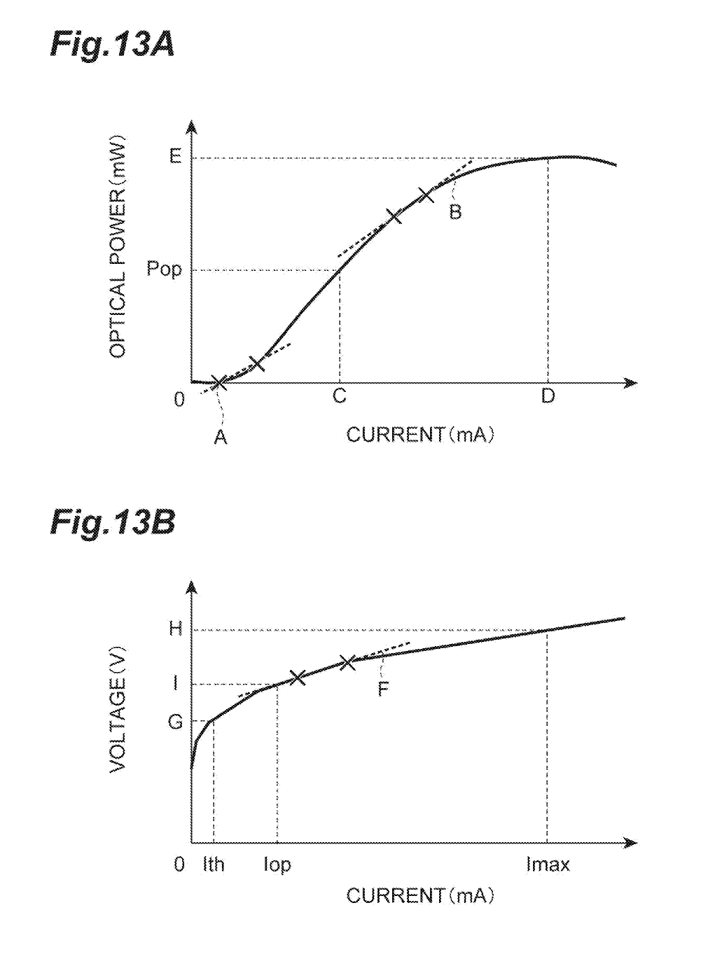

FIG. 13A is a graph showing current-optical output characteristics, measured by the measuring apparatus 1A, of the VCSEL 50. The following values (1) to (5) are calculated using the current-optical power characteristics in the figure.

(1) Threshold current Ith: Current value (“A value” in the figure) which is the x-intercept (the current axis-intercept) of the straight line connecting two points on the given light power curve.
(2) Slope efficiency η (W/A): Slope of “straight line B” connecting two points on the given light power curve.
(3) Operating current Iop: Drive current value (“C value” in the figure) at a specified optical power (Pop).
(4) Maximum driving current value Imax (“D value” in the figure).
(5) Maximum light output power Pmax (“E value” in the figure).

FIG. 13B is a graph showing current-voltage characteristics, measured by the measuring apparatus 1A, of the VCSEL 50. The following values (6) to (9) are calculated using the current-voltage characteristics in the figure.

(6) Differential resistance Rs: Slope of the “straight line F” connecting two points on the curve in the figure (in a forward voltage).
(7) Threshold voltage Vth: Forward voltage value at the threshold current Ith (“G value” in the figure).
(8) Maximum driving voltage Vmax.

The measuring probe and the measuring apparatus according to the present embodiments are not limited to the above-described examples and various other modifications are possible. For example, in the above-described example, the measuring probe and the measuring apparatus are used for measuring the operation characteristics of the VCSEL. But, the measuring probe and the measuring device are not limited to the measurement of the VCSEL, and can be used to measure various semiconductor optical devices, such as light receiving semiconductor device. In the above embodiments, the measuring apparatus includes multiple measuring probes, but if needed, the measuring apparatus may have a single measuring probe.

The measuring probe and the measuring apparatus can bring the two probing needles into simultaneous contact with a small electrode of the semiconductor optical device easily.

Having described and illustrated the principle of the invention in a preferred embodiment thereof, it is appreciated by those having skill in the art that the invention can be modified in arrangement and detail without departing from such principles. We therefore claim all modifications and variations coining within the spirit and scope of the following claims.

What is claimed is:

1. A probing device comprising:
a first probing needle including a first portion, a bent portion and a second portion, the first portion having a probing tip, and the bent portion connecting the first portion with the second portion;
a second probing needle including a first portion, a bent portion and a second portion, the first portion having a probing tip, and the bent portion connecting the first portion with the second portion;
a supporting member including an insulating base, the insulating base having a principal face and a back face, the principal face being opposite to the back face, and the first probing needle and the second probing needle being supported by the insulating base on the back face; and
a holder holding the first portion of the first probing needle and the first portion of the second probing needle, the holder electrically isolating the first probing needle from the second probing needle, and the holder being apart from the probing tip of the first probing needle and the probing tip of the second probing needle.

2. The probing device according to claim 1, wherein the holder has a first opening and a second opening, and the first portion of the first probing needle and the first portion of the second probing needle pass through the first opening and the second opening, respectively.

3. The probing device according to claim 1, wherein the holder has a first through-hole and a second through-hole, and the first portion of the first probing needle and the first portion of the second probing needle pass through the first through-hole and the second through-hole, respectively.

4. The probing device according to claim 3, wherein the holder has one end and another end, and the first through-hole and the second through-hole extend from the one end and the other end.

5. The probing device according to claim 1, wherein the holder has a first holding portion that holds the first portion of the first probing needle, and a second holding portion that holds the first portion of the second probing needle.

6. The probing device according to claim 5, wherein the holder has an inner face that defines the first holding portion and the inner face is in contact with the first probing needle.

7. The probing device according to claim 1, further comprising an optical fiber supported by the insulating base, the optical fiber having a tip end.

8. The probing device according to claim 1, wherein the first probing needle and the second probing needle are press-fitted to the holder.

9. The probing device according to claim 1, wherein the first portion of the first probing needle and the second probing needle are fixed to the holder with adhesive.

10. The probing device according to claim 1, wherein the first portion of the first probing needle includes a first part with the probing tip, a second part that is held by the holder, and a third part that is connected to the bent portion of the first probing needle.

11. The probing device according to claim 1, wherein the holder aligns the probing tip of the first probing needle and the probing tip of the second probing needle with each other.

12. The probing device according to claim 1, wherein a distance between the probing tip of the first probing needle and the probing tip of the second probing needle is not more than 50 micrometers.

13. The probing device according to claim 1, wherein the holder includes resin.

14. The probing device according to claim 1, wherein the holder includes ceramics.

15. The probing device according to claim 1, wherein the supporting member has a first conductor and a second conductor, and the first conductor and the second conductor are connected to the second portion of the first probing needle and the second portion of the second probing needle, respectively.
